(19) United States
(12) Patent Application Publication
(10) Pub. No.: US 2025/0343529 A1
(43) Pub. Date: Nov. 6, 2025

(54) PAIR OF RESONATORS WITH IMPROVED TURNING DISTANCE

(71) Applicant: Skyworks Solutions, Inc., Irvine, CA (US)

(72) Inventors: Justin Liao, Irvine, CA (US); Benjamin Paul Abbott, Irvine, CA (US); Nan Wu, Irvine, CA (US)

(21) Appl. No.: 19/187,419

(22) Filed: Apr. 23, 2025

Related U.S. Application Data
(60) Provisional application No. 63/643,195, filed on May 6, 2024.
(60) Provisional application No. 63/643,209, filed on May 6, 2024.
(60) Provisional application No. 63/643,244, filed on May 6, 2024.

(51) Int. Cl. H03H 9/54; H03H 9/02; H03H 9/205

(52) U.S. Cl. CPC H03H 9/54; H03H 9/02086; H03H 9/205

(57) ABSTRACT

An acoustic wave filter is disclosed. The acoustic wave filter has a first port and a second port. The acoustic wave filter can include a first bulk acoustic wave resonator having a first shape, a first active area, and a first shape factor, and a second bulk acoustic wave resonator having a second shape, a second active area, and a second shape factor different than the first shape factor. The first and second bulk acoustic wave resonators are a pair of resonators electrically connected adjacent to one another. The first area and the second area are the same, and a turning distance between the first shape and the second shape is greater than zero and less than 0.3.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/643,195, filed May 6, 2024, titled “ACOUSTIC WAVE FILTER WITH REDUCED NONLINEAR RESPONSES,” U.S. Provisional Patent Application No. 63/643,209, filed May 6, 2024, titled “RESONATORS HAVING FACTOR DIFFERENCES,” and U.S. Provisional Patent Application No. 63/643,244, filed May 6, 2024, titled “PAIR OF RESONATORS WITH IMPROVED TURNING DISTANCE,” are hereby incorporated by reference under 37 CFR 1.57 in their entirety.

### BACKGROUND

### Technical Field

The disclosed technology relates to acoustic wave devices. Embodiments of this disclosure relate to filters with bulk acoustic wave devices.

### Description of Related Technology

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

An acoustic wave filter can include a plurality of acoustic wave resonators arranged to filter a radio frequency signal. Example acoustic wave resonators include surface acoustic wave (SAW) resonators and bulk acoustic wave (BAW) resonators. In BAW resonators, acoustic waves propagate in the bulk of a piezoelectric layer. Example BAW resonators include film bulk acoustic wave resonators (FBARs) and BAW solidly mounted resonators (SMRs).

There are technical challenges related to reducing the filter size while suppressing unwanted signal components such as a second harmonic spur.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to an acoustic wave filter including: a first bulk acoustic wave resonator having a first shape, a first active area, and a first shape factor; and a second bulk acoustic wave resonator having a second shape, a second active area, and a second shape factor, the first and second bulk acoustic wave resonators arranged to cancel a nonlinear response, the first shape and the second shape being different, the first area and the second area being the same, and a difference between the first shape factor and the second shape factor being greater than zero and equal to or less than 0.1.

In some embodiments, the techniques described herein relate to an acoustic wave filter wherein the first and second bulk acoustic wave resonators define a pair of series resonators.

In some embodiments, the techniques described herein relate to an acoustic wave filter wherein the first and second bulk acoustic wave resonators define a pair of shunt resonators.

In some embodiments, the techniques described herein relate to an acoustic wave filter wherein the difference between the first shape factor and the second shape factor is in a range between 0.001 and 0.1.

In some embodiments, the techniques described herein relate to an acoustic wave filter wherein the difference between the first shape factor and the second shape factor is equal to or less than 0.05.

In some embodiments, the techniques described herein relate to an acoustic wave filter wherein the difference between the first shape factor and the second shape factor is equal to or less than 0.01.

In some embodiments, the techniques described herein relate to an acoustic wave filter wherein the acoustic wave filter having a first port and a second port, the first and second bulk acoustic wave resonators are a pair of series or parallel resonators closest to the first port.

In some embodiments, the techniques described herein relate to an acoustic wave filter wherein the first port is an antenna port.

In some embodiments, the techniques described herein relate to an acoustic wave filter wherein the first and second bulk acoustic wave resonators are a pair of resonators electrically connected adjacent to one another.

In some embodiments, the techniques described herein relate to an acoustic wave filter wherein a turning distance between the first shape and the second shape is greater than zero and less than 0.3.

In some embodiments, the techniques described herein relate to a radio frequency module including: the acoustic wave filter; radio frequency circuitry; and a package structure enclosing the filter and the radio frequency circuitry.

In some embodiments, the techniques described herein relate to a radio frequency system including: an antenna; the acoustic wave filter; and an antenna switch configured to selectively, electrically connect the antenna and a signal path that includes the filter.

In some aspects, the techniques described herein relate to a method of forming an acoustic wave filter, the method including: providing a first bulk acoustic wave resonator on a carrier; providing a second bulk acoustic wave resonator on the carrier, the first and second bulk acoustic wave resonators configured to cancel a nonlinear response; and varying shapes of the first and second bulk acoustic wave resonators such that the first bulk acoustic wave resonator has a first shape, a first active area, and a first shape factor and the second bulk acoustic wave resonator having a second shape, a second active area, and a second shape factor, the first shape and the second shape being different, the first area and the second area being the same, and a difference between the first shape factor and the second shape factor being greater than zero and equal to or less than 0.1.

In some embodiments, the techniques described herein relate to a method wherein the first and second bulk acoustic wave resonators define a pair of series resonators.

In some embodiments, the techniques described herein relate to a method wherein the first and second bulk acoustic wave resonators define a pair of shunt resonators.

In some embodiments, the techniques described herein relate to a method wherein the difference between the first shape factor and the second shape factor is equal to or less than 0.05.

In some embodiments, the techniques described herein relate to a method wherein the acoustic wave filter having a first port and a second port, the first and second bulk acoustic wave resonators are a pair of series or parallel resonators closest to the first port.

In some embodiments, the techniques described herein relate to a method wherein the first port is an antenna port.

In some embodiments, the techniques described herein relate to a method wherein the first and second bulk acoustic wave resonators are a pair of resonators electrically connected adjacent to one another.

In some embodiments, the techniques described herein relate to a method wherein a turning distance between the first shape and the second shape is greater than zero and less than 0.3.

In some aspects, the techniques described herein relate to an acoustic wave filter having a first port and a second port, the acoustic wave filter including: a first bulk acoustic wave resonator having a first shape, a first active area, and a first shape factor; and a second bulk acoustic wave resonator having a second shape, a second active area, and a second shape factor, the first and second bulk acoustic wave resonators being a pair of series or parallel resonators closer to the first port than other bulk acoustic wave resonators, the first shape and the second shape are different, the first area and the second area being the same, and a difference between the first shape factor and the second shape factor being greater than zero and equal to or less than 0.1.

In some embodiments, the techniques described herein relate to an acoustic wave filter wherein the first port is an antenna port.

In some embodiments, the techniques described herein relate to an acoustic wave filter wherein the first bulk acoustic wave resonator is positioned closest to the antenna port.

In some embodiments, the techniques described herein relate to an acoustic wave filter wherein the other bulk acoustic wave resonators include a third bulk acoustic wave resonator electrically connected between the first resonator and the second port.

In some embodiments, the techniques described herein relate to an acoustic wave filter wherein the first and second bulk acoustic wave resonators configured to cancel a nonlinear response.

In some embodiments, the techniques described herein relate to an acoustic wave filter wherein the difference between the first shape factor and the second shape factor is in a range between 0.001 and 0.1.

In some embodiments, the techniques described herein relate to an acoustic wave filter wherein the difference between the first shape factor and the second shape factor is equal to or less than 0.05.

In some embodiments, the techniques described herein relate to an acoustic wave filter wherein the first and second bulk acoustic wave resonators are a pair of resonators electrically connected adjacent to one another.

In some embodiments, the techniques described herein relate to an acoustic wave filter wherein a turning distance between the first shape and the second shape is greater than zero and less than 0.3.

In some embodiments, the techniques described herein relate to a radio frequency module including: the acoustic wave filter; radio frequency circuitry; and a package structure enclosing the filter and the radio frequency circuitry.

In some embodiments, the techniques described herein relate to a radio frequency system including: an antenna; the acoustic wave filter; and an antenna switch configured to selectively, electrically connect the antenna and a signal path that includes the filter.

In some aspects, the techniques described herein relate to a method of forming an acoustic wave filter having a first port and a second port, the method including: providing a first bulk acoustic wave resonator on a carrier; providing a second bulk acoustic wave resonator on the carrier, the first and second bulk acoustic wave resonators, the first and second bulk acoustic wave resonators being a pair of series or parallel resonators closer to the first port than other bulk acoustic wave resonators; and varying shapes of the first and second bulk acoustic wave resonators such that the first bulk acoustic wave resonator has a first shape, a first active area, and a first shape factor and the second bulk acoustic wave resonator having a second shape, a second active area, and a second shape factor, the first shape and the second shape being different, the first area and the second area being the same, and a difference between the first shape factor and the second shape factor being greater than zero and equal to or less than 0.1.

In some embodiments, the techniques described herein relate to a method wherein the first port is an antenna port.

In some embodiments, the techniques described herein relate to a method wherein the first bulk acoustic wave resonator is positioned closest to the antenna port.

In some embodiments, the techniques described herein relate to a method wherein the other bulk acoustic wave resonators include a third bulk acoustic wave resonator electrically connected between the first resonator and the second port.

In some embodiments, the techniques described herein relate to a method wherein the first and second bulk acoustic wave resonators configured to cancel a nonlinear response.

In some embodiments, the techniques described herein relate to a method wherein the difference between the first shape factor and the second shape factor is in a range between 0.001 and 0.1.

In some embodiments, the techniques described herein relate to a method wherein the difference between the first shape factor and the second shape factor is equal to or less than 0.05.

In some embodiments, the techniques described herein relate to a method wherein the first and second bulk acoustic wave resonators are a pair of resonators electrically connected adjacent to one another.

In some embodiments, the techniques described herein relate to a method wherein a turning distance between the first shape and the second shape is greater than zero and less than 0.3.

In some aspects, the techniques described herein relate to an acoustic wave filter including: a first bulk acoustic wave resonator having a first shape, a first active area, and a first shape factor; and a second bulk acoustic wave resonator having a second shape, a second active area, and a second shape factor different than the first shape factor, the first and second bulk acoustic wave resonators being a pair of resonators electrically connected adjacent to one another, the first area and the second area being the same, and a turning distance between the first shape and the second shape being greater than zero and less than 0.3.

In some embodiments, the techniques described herein relate to an acoustic wave filter wherein the first and second bulk acoustic wave resonators define a pair of series resonators.

In some embodiments, the techniques described herein relate to an acoustic wave filter wherein the first and second bulk acoustic wave resonators define a pair of shunt resonators.

In some embodiments, the techniques described herein relate to an acoustic wave filter wherein the difference between the first shape factor and the second shape factor is in a range between 0.001 and 0.1.

In some embodiments, the techniques described herein relate to an acoustic wave filter wherein the difference between the first shape factor and the second shape factor is equal to or less than 0.05.

In some embodiments, the techniques described herein relate to an acoustic wave filter wherein the difference between the first shape factor and the second shape factor is equal to or less than 0.01.

In some embodiments, the techniques described herein relate to an acoustic wave filter wherein the acoustic wave filter having a first port and a second port, the first and second bulk acoustic wave resonators are a pair of series or parallel resonators closest to the first port.

In some embodiments, the techniques described herein relate to an acoustic wave filter wherein the first port is an antenna port.

In some embodiments, the techniques described herein relate to an acoustic wave filter wherein the first and second bulk acoustic wave resonators configured to cancel a nonlinear response.

In some embodiments, the techniques described herein relate to an acoustic wave filter wherein the turning distance between the first shape and the second shape is in a range between 0.01 and 0.3.

In some embodiments, the techniques described herein relate to a radio frequency module including: the acoustic wave filter; radio frequency circuitry; and a package structure enclosing the filter and the radio frequency circuitry.

In some aspects, the techniques described herein relate to a radio frequency system including: an antenna; an acoustic wave filter including a first bulk acoustic wave resonator having a first shape, a first active area, and a first shape factor, and a second bulk acoustic wave resonator having a second shape, a second active area, and a second shape factor different than the first shape factor, the first and second bulk acoustic wave resonators being a pair of resonators electrically connected adjacent to one another, the first area and the second area being the same, and a turning distance between the first shape and the second shape being greater than zero and less than 0.3; and an antenna switch configured to selectively, electrically connect the antenna and a signal path that includes the filter.

In some aspects, the techniques described herein relate to a method of forming an acoustic wave filter, the method including: providing a first bulk acoustic wave resonator on a carrier; providing a second bulk acoustic wave resonator on the carrier, the first and second bulk acoustic wave resonators being a pair of resonators electrically connected adjacent to one another; and varying shapes of the first and second bulk acoustic wave resonators such that the first bulk acoustic wave resonator has a first shape, a first active area, and a first shape factor and the second bulk acoustic wave resonator having a second shape, a second active area, and a second shape factor that is different than the first shape factor, and a turning distance between the first shape and the second shape being greater than zero and less than 0.3.

In some embodiments, the techniques described herein relate to a method wherein the first and second bulk acoustic wave resonators define a pair of series resonators.

In some embodiments, the techniques described herein relate to a method wherein the first and second bulk acoustic wave resonators define a pair of shunt resonators.

In some embodiments, the techniques described herein relate to a method wherein the difference between the first shape factor and the second shape factor is equal to or less than 0.05.

In some embodiments, the techniques described herein relate to a method wherein the acoustic wave filter having a first port and a second port, the first and second bulk acoustic wave resonators are a pair of series or parallel resonators closest to the first port.

In some embodiments, the techniques described herein relate to a method wherein the first port is an antenna port.

In some embodiments, the techniques described herein relate to a method wherein the first and second bulk acoustic wave resonators configured to cancel a nonlinear response.

In some embodiments, the techniques described herein relate to a method wherein a turning distance between the first shape and the second shape is in a range between 0.01 and 0.3.

### BRIEF DESCRIPTION OF THE DRAWINGS

Embodiments of this disclosure will now be described, by way of non-limiting example, with reference to the accompanying drawings.

FIG. 1A is a schematic diagram showing a first resonator and a second resonator coupled in series.

FIG. 1B is a schematic diagram showing the first resonator and the second resonator coupled in parallel.

FIG. 2 is a schematic top plan view of a filter showing resonator layout according to an embodiment.

FIG. 3 is a schematic circuit diagram of the filter of FIG. 2.

FIG. 4A is an enlarged view of a portion of the filter of FIG. 2 including a first set of series resonators.

FIG. 4B is an enlarged view of a portion of the filter of FIG. 2 including a first set of shunt resonators.

FIG. 5 is a flow chart showing a method of forming an acoustic wave filter according to an embodiment.

FIGS. 6A, 6B, 6C, and 6D are schematic diagrams of multiplexers that include a filter with one or more bulk acoustic wave (BAW) resonators according to an embodiment.

FIGS. 7, 8, and 9 are schematic block diagrams of modules that include a filter with one or more BAW resonators according to an embodiment.

FIG. 10 is a schematic block diagram of a wireless communication device that includes a filter with one or more BAW resonators according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other. The headings provided herein are for convenience only and are not intended to affect the meaning or scope of the claims.

In bulk acoustic wave (BAW) technology, a harmonic spur (e.g., a second harmonic (H2) spur) is an unwanted signal component that occurs at a frequency outside of the desired signal (at twice the frequency of the desired signal). BAW devices utilize acoustic waves propagating through a piezoelectric material to manipulate and filter radio frequency (RF) signals. However, these devices can generate harmonics due to non-linear effects within the material or device structure. The second harmonic spur can potentially cause interference and degradation of the desired signal quality.

A pair of series cascaded resonators and/or a pair of shunt splitting resonators with opposite polarities of the piezoelectric layer can be utilized to suppress or cancel the second harmonic spur. Reducing the filter size while reducing the second harmonic spur can be challenging because when shapes of the resonators are adjusted for improved resonator layout to reduce the filter size, the shape differences among the resonators, especially between the pair of series or shunt resonators, can contribute to causing significant amount of the second harmonic spur.

Various embodiments disclosed herein relate to improving a resonator layout to reduce a filter size while providing a desired second harmonic spur (H2) cancelation. A resonator layout method used herein can be referred to as mesh-layout. In the mesh-layout, vertices for each resonator in a filter can be defined and spaces between resonators can be reduced by adjusting the shapes of the resonators within the vertices while maintaining the areas. In the mesh-layout, various limitations and rules can be applied. For example, the rules can include the minimum spacings between adjacent resonators, minimum and maximum angles for the vertices, and aspect ratio requirements. The filter can include a first bulk acoustic wave (BAW) device (e.g., a first resonator) and a second BAW device (e.g., a second resonator) that are configured to cancel the second harmonic spur. The first and second resonators can be a pair of series resonators or a pair of shunt resonators. The pair of series or shunt resonators can be the closest series or shunt resonators from a port (e.g. an antenna port) of the filter. The piezoelectric layer of the first resonator and the piezoelectric layer of the second resonator can have opposite polarities. The first resonator has a first shape, a first active area, and a first shape factor. The second resonator has a second shape, a second active area, and a second shape factor. The first shape and the second shape can be different and the first active area and the second active area can be the same. A difference between the first shape factor and the second shape factor can be greater than zero and equal to or less than 0.1. A turning distance between the first shape and the second shape can be less than 0.3. The turning distance between two poly-shape objects is a measure of how closely their shapes match, regardless of rotation or scaling. A turning distance close to zero indicates a near match. The larger the value, the more the two shapes differ. The filter according to various embodiments disclosed herein enable a significant reduction of the second harmonic spur. Any suitable principles and advantages of BAW resonators disclosed herein can be implemented together with each other.

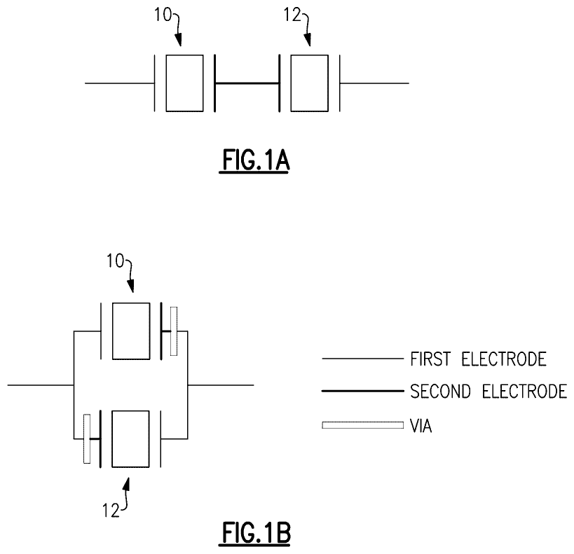

FIG. 1A is a schematic diagram showing a first resonator 10 and a second resonator 12 coupled in series. FIG. 1B is a schematic diagram showing the first resonator 10 and the second resonator 12 coupled in parallel. The first resonator 10 and the second resonator 12 coupled in series can define series cascade resonators, and the first resonator 10 and the second resonator 12 coupled in parallel can define shunt splitting resonators.

In series cascade resonators, resonators (e.g., the first and second resonators 10, 12) can be connected sequentially along the signal path, with each resonator 10, 12 designed to have opposite polarities of the piezoelectric layers. The series cascade resonators can generate opposite phase signals at the resonance frequency, effectively cancelling out the second harmonic components or nonlinear responses as the signal passes through each resonator 10, 12.

In shunt splitting resonators, resonators (e.g., the first and second resonators 10, 12) can be arranged in parallel or shunt to the signal path, with each resonator 10, 12 possessing opposite polarities of the piezoelectric layers. When the input signal is divided among the resonators 10, 12, the opposite polarities of the piezoelectric layers allow for selective attenuation or cancellation of the second harmonic components or nonlinear responses. By leveraging resonators 10, 12 with opposite polarities in both configurations, BAW filters can achieve significant reduction in unwanted harmonic content, leading to cleaner output signals and improved performance in communication systems and other applications.

The electrodes of the first resonator 10 and the electrodes of the second resonator 12 can be connected in a way so as to reverse the field direction (e.g., current or voltage direction) in the piezoelectric layers, which can enable the nonlinear response cancelation. From the perspectives of the nonlinear response cancelation such as the second harmonic spur cancellation, it can be beneficial to use identical resonator structures for the first and second resonators 10, 12. However, when the first and second resonators 10, 12 have the same shape, resonator layout of the filter may not be ideal for size reduction. On the other hand, when the shapes of the first and second resonators 10, 12 are altered for size reduction, the nonlinear response cancelation performance can degrade. Embodiments disclosed herein enable a filter to have reduced size while maintaining desired nonlinear response cancelation performance.

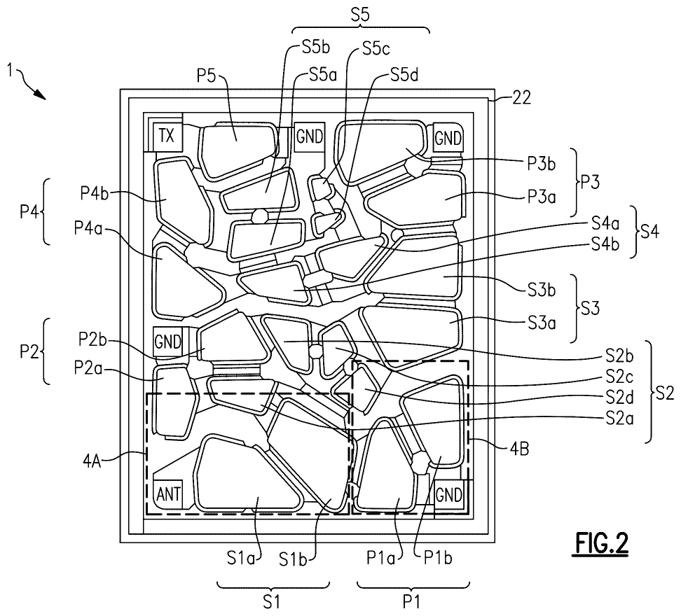

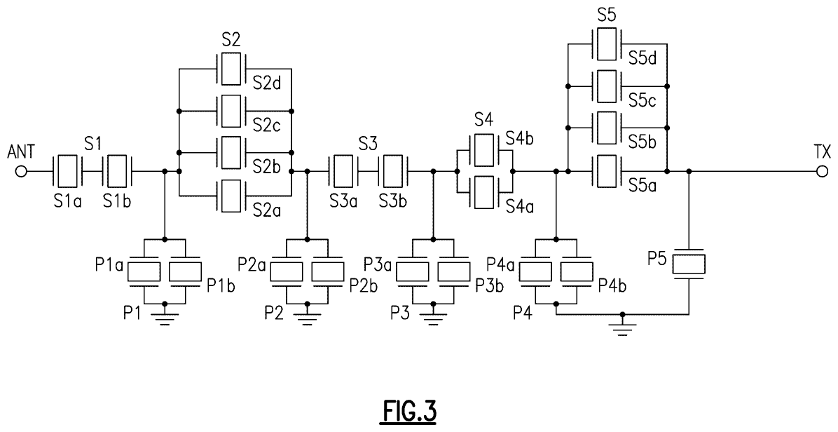

FIG. 2 is a schematic top plan view of a filter 1 showing a resonator layout according to an embodiment. FIG. 3 is a schematic circuit diagram of the filter 1 of FIG. 2. The filter 1 can include a first set of series resonators S1 including resonators S1a, S1b, a second set of series resonators S2 including resonators S2a, S2b, S2c, S2d, a third set of series resonators S3 including resonators S3a, S3b, a fourth set of series resonators S4 including resonators S4a, S4b, and a fifth set of series resonators S5 including resonators S5a, S5b, S5c, S5d that are connected in series along the signal path. The filter 1 can include a first set of shunt resonators P1 including resonators P1a, P1b, a second set of shunt resonators P2 including resonators P2a, P2b, a third set of shunt resonators P3 including resonators P3a, P3b, a fourth set of shunt resonators P4 including resonators P4a, P4b, and a fifth shunt resonator P5 that are connected in parallel to the signal path. The resonators S1a, S1b, S2a, S2b, S2c, S2d, S3a, S3b, S4a, S4b, S5a, S5b, S5c, S5d, P1a, P1b, P2a, P2b, P3a, P3b, P4a, P4b, P5 can be provided on a carrier 22 electrically connected between a first port (e.g., antenna port ANT) and a second port (e.g., transmit port TX).

The resonator layout of filter 1 is an example result of a mesh-layout. Before the mesh-layout, each set of resonators S1-S5, P1-P4 can include resonators that are identical in shape and area. Because of the identical shapes and areas, the resonators may waste areas on a carrier to which the resonators are positioned. The mesh-layout can reduce the waste areas by improving the resonator shapes and resonator locations on the carrier 22. However, when the resonator shapes are altered significantly, the filter 1 may not operate with desired second harmonic spur cancellation performance. Therefore, according to various embodiments, a shape factor can be an improvement factor in the mesh-layout to reduce the filter size while providing desired second harmonic spur cancellation performance. The first set of series resonators S1 and the first set of shunt resonators P1 will be used as examples to describe the principle and advantages of this disclosure.

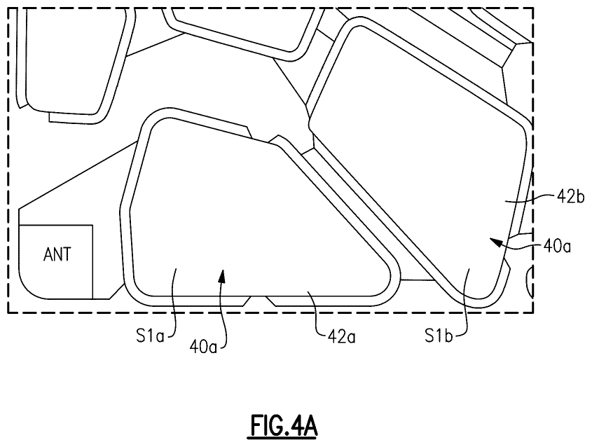

FIG. 4A is an enlarged view of a portion of the filter 1 of FIG. 2 including the first set of series resonators S1 including the resonators S1a, S1b. The resonators S1a, S1b can be the same as or generally similar to the first and second resonators 10, 12 of FIG. 1A. The resonators S1a, S1b can be adjacent to one another. The resonators S1a, S1b can be configured to cancel or suppress the nonlinear responses, such as the second harmonic (H2) spur. The electrodes of the resonator Sla and the electrodes of the resonator S1b can be connected in a way so as to reverse the field direction (e.g., current or voltage direction) in the piezoelectric layers, which can enable the nonlinear response cancelation.

The resonator Sla has a first shape, a first active area 40a, and a first shape factor, and the resonator S1b has a second shape, a second active area 40b, and a second shape factor. The first and second shapes can be the two-dimensional shapes of corresponding active regions of the resonators S1a, S1b as seen in the top plan view. An active region is a region where two electrodes and a piezoelectric layer overlap. The first and second active areas 40a, 40b can be the lateral area sizes of the active regions of the resonators S1a, S1b. The first shape factor can be calculated by dividing a first perimeter 42a of the first shape by a perimeter of a circle having the first active area 40a. The second shape factor can be calculated by dividing a second perimeter 42b of the second shape by a perimeter of a circle having the second active area 40b. The first active area 40a can be surrounded by the first perimeter 42a and the second active area 40b can be surrounded by the second perimeter 42b.

The first and second shapes of the resonators S1a, S1b can be different. In some embodiments, a turning distance between the first and second shapes of the resonators S1a, S1b can be greater than zero and less than 0.3. For example, the turning distance between the first and third shapes can be in a range between 0.01 and 0.3, 0.01 and 0.25, 0.01 and 0.2, 0.01 and 0.1, or 0.05 and 0.25. The first and second active areas 40a, 40b of the resonators S1a, S1b can be the same. In some cases, the first and second active areas 40a, 40b are configured to be the same but there may be a manufacturing tolerance that makes the first and second active areas slightly different. For example, a difference between the first and second active areas 40a, 40b can be within 0.01% and still be considered to have the same active areas. The first and second shape factors of the resonators S1a, S1b can be generally similar. In some embodiments, a difference between the first and second shape factors can be equal to or less than 0.1. For example, the difference between the first and second shape factors can be in a range between 0 and 0.1, 0 and 0.05, 0 and 0.01, 0.001 and 0.1, 0.001 and 0.05, or 0.001 and 0.01.

FIG. 4B is an enlarged view of a portion of the filter 1 of FIG. 2 including the first set of shunt resonators P1 including the resonators P1a, P1b. The resonators P1a, P1b can be the same as or generally similar to the first and second resonators 10, 12 of FIG. 1B. The resonators P1a, P1b can be adjacent to one another. The resonators P1a, P1b can be configured to cancel or suppress the nonlinear responses, such as the second harmonic (H2) spur. The electrodes of the resonator Sla and the electrodes of the resonator S1b can be connected in a way so as to reverse the field direction (e.g., current or voltage direction) in the piezoelectric layers, which can enable the nonlinear response cancelation.

As with the resonators S1a, S1b, the resonator P1a has a first shape, a first active area, and a first shape factor, and the resonator P1b has a second shape, a second active area, and a second shape factor. The first and second shapes can be the two-dimensional shapes of the resonators P1a, P1b as seen in the top plan view. The first and second active areas can be the lateral areas of the resonators P1a, P1b. The first shape factor can be calculated by dividing a first perimeter of the first shape by a perimeter of a circle having the first active area. The second shape factor can be calculated by dividing a second perimeter of the second shape by a perimeter of a circle having the second active area.

The first and second shapes of the resonators P1a, P1b can be different. In some embodiments, a turning distance between the first and second shapes of the resonators P1a, P1b can be greater than zero and less than 0.3. For example, the turning distance between the first and third shapes can be in a range between 0.01 and 0.3, 0.01 and 0.25, 0.01 and 0.2, 0.01 and 0.1, or 0.05 and 0.25. The first and second active areas of the resonators P1a, P1b can be the same. In some cases, the first and second active areas are configured to be the same but there may be a manufacturing tolerance that makes the first and second active areas slightly different. For example, a difference between the first and second active areas of the resonators P1a, P1b can be within 0.01% and still be considered to have the same active areas. The first and second shape factors of the resonators P1a, P1b can be generally similar. In some embodiments, a difference between the first and second shape factors can be equal to or less than 0.1. For example, the difference between the first and second shape factors can be in a range between 0 and 0.1, 0 and 0.05, 0 and 0.01, 0.001 and 0.1, 0.001 and 0.05, or 0.001 and 0.01.

In some applications, the second harmonic (H2) spur may be dominated by the first stage resonators closest to the antenna port ANT, and it can be particularly significant to make the shape factors of the resonators S1a, S1b or the shape factors of the resonators P1a, P1b as close as possible. For example, when the shape factors of the resonators S1a, S1b or the shape factors of the resonators P1a, P1b are within 0.1, about ten times reduction in the second harmonic (H2) may be achieved as compared to dissimilar shape factors, and when the shape factors of the resonators S1a, S1b or the shape factors of the resonators P1a, P1b are within 0.05, about twenty times reduction in the second harmonic (H2) may be achieved as compared to dissimilar shape factors.

Any pair of resonators in the first set of series resonators S1, the second set of series resonators S2, the third set of series resonators S3, the fourth set of series resonators S4, the fifth set of series resonators S5, the first set of shunt resonators P1, the second set of shunt resonators P2, the third set of shunt resonators P3, or the fourth set of shunt resonators P4 can implement any suitable principles and advantages disclosed herein. For example, any pair of resonators within the first set of series resonators S1, the second set of series resonators S2, the third set of series resonators S3, the fourth set of series resonators S4, the fifth set of series resonators S5, the first set of shunt resonators P1, the second set of shunt resonators P2, the third set of shunt resonators P3, or the fourth set of shunt resonators P4 can have a shape factor difference as disclosed herein. The resonators S1a, S1b, S2a, S2b, S2c, S2d, S3a, S3b, S4a, S4b, S5a, S5b, S5c, S5d, P1a, P1b, P2a, P2b, P3a, P3b, P4a, P4b, P5 can include any suitable types of BAW resonators, such as a film bulk acoustic wave resonator (FBAR) or a BAW solidly mounted resonator (SMR).

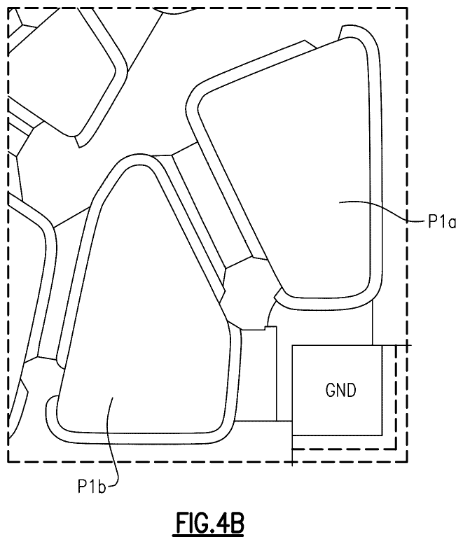

Various embodiments of filters disclosed herein can be manufactured in any suitable manner. An example method of forming a filter according to an embodiment will be described with respect to FIG. 5.

FIG. 5 is a flow chart showing a method of forming an acoustic wave filter according to an embodiment. Components shown in FIG. 2 will be referred to in the description below. The method can include providing resonators S1a, S1b, S2a, S2b, S2c, S2d, S3a, S3b, S4a, S4b, S5a, S5b, S5c, S5d, P1a, P1b, P2a, P2b, P3a, P3b, P4a, P4b, P5 on a carrier 22 (block 50). The series resonators S1a, S1b, S2a, S2b, S2c, S2d, S3a, S3b, S4a, S4b, S5a, S5b, S5c, S5d are electrically connected in series along a signal path between a first port (e.g., an antenna port (ANT)) and a second port (e.g., a transmit or receive port (TX/RX)) and the shunt resonators P1a, P1b, P2a, P2b, P3a, P3b, P4a, P4b, P5 are electrically connected in parallel to the signal path.

The method can include defining vertices for each resonator S1a, S1b, S2a, S2b, S2c, S2d, S3a, S3b, S4a, S4b, S5a, S5b, S5c, S5d, P1a, P1b, P2a, P2b, P3a, P3b, P4a, P4b, P5 on the carrier 22 (block 52). Based at least in part on the defied vertices, the resonators S1a, S1b, S2a, S2b, S2c, S2d, S3a, S3b, S4a, S4b, S5a, S5b, S5c, S5d, P1a, P1b, P2a, P2b, P3a, P3b, P4a, P4b, P5 can be meshed (block 54). Shapes and locations of the resonator S1a, S1b, S2a, S2b, S2c, S2d, S3a, S3b, S4a, S4b, S5a, S5b, S5c, S5d, P1a, P1b, P2a, P2b, P3a, P3b, P4a, P4b, P5 can be improved or varied in accordance with rules and/or limitations (block 56). For example, the rules and/or limitations can include shape factor ranges, minimum spacings between adjacent resonators, minimum and maximum angles for the vertices, and aspect ratio requirements. Active area sizes of the resonators S1a, S1b, S2a, S2b, S2c, S2d, S3a, S3b, S4a, S4b, S5a, S5b, S5c, S5d, P1a, P1b, P2a, P2b, P3a, P3b, P4a, P4b, P5 can be maintained the same during the shape and location improvement process. At least one or more processes of the method of forming the acoustic wave filter can be automated. The rules and/or limitations may enable the automated processes to complete more quickly. In some embodiments, the rules and/or limitations can simplify the automated processes.

Acoustic wave filters disclosed herein can filter a radio frequency signal. Example filter topologies can include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, the principles and advantages disclosed herein can be implemented in filters with one or more other types of resonators and/or with passive impedance elements, such as one or more inductors and/or one or more capacitors.

A filter that includes BAW resonators in accordance with any suitable principles and advantages disclosed herein can be arranged to filter a radio frequency signal in a fifth generation 5G NR operating band within Frequency Range 1 (FR1). FR1 can be from 410 MHz to 7.125 gigahertz (GHz), for example, as specified in a current 5G NR specification. A filter that includes an acoustic wave resonator in accordance with any suitable principles and advantages disclosed herein can be arranged to filter a radio frequency signal in a fourth generation (4G) Long Term Evolution (LTE) operating band. A filter that includes an acoustic wave resonator in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio-Dual Connectivity (ENDC) application. A multiplexer including any such filters can include one or more other filters with a passband corresponding to a 5G NR operating band and/or a 4G LTE operating band.

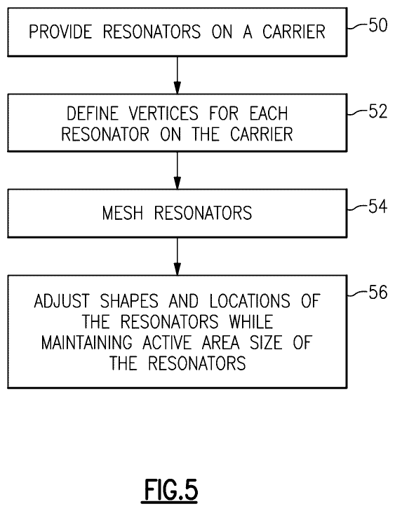

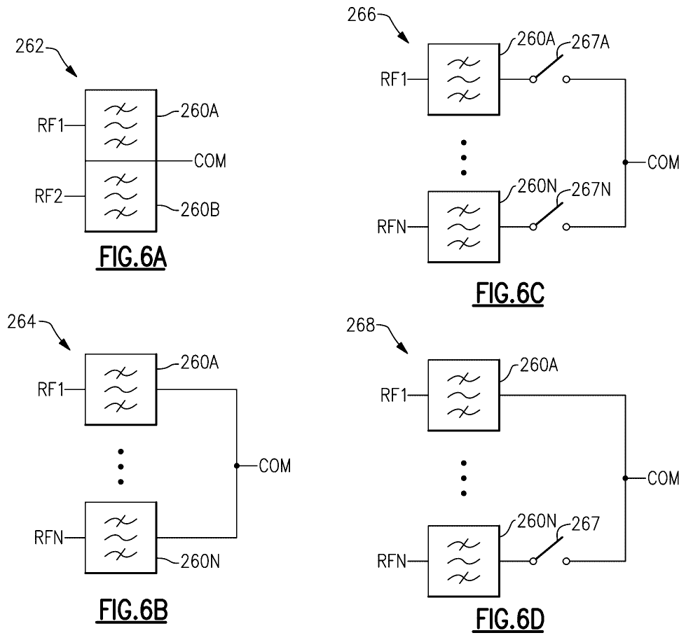

The BAW devices disclosed herein can be implemented in a standalone filter and/or in a filter of any suitable multiplexer. Such filters can be any suitable topology, such as a ladder filter topology. The filter can be a band pass filter arranged to filter a 4G LTE band and/or 5G NR band. Example multiplexers will be discussed with reference to FIGS. 6A to 6D. Any suitable principles and advantages of these multiplexers can be implemented together with each other.

FIG. 6A is a schematic diagram of a duplexer 262 that includes an acoustic wave filter according to an embodiment. The duplexer 262 includes a first filter 260A and a second filter 260B coupled together at a common node COM. One of the filters of the duplexer 262 can be a transmit filter and the other of the filters of the duplexer 262 can be a receive filter. In some other instances, such as in a diversity receive application, the duplexer 262 can include two receive filters. Alternatively, the duplexer 262 can include two transmit filters. The common node COM can be an antenna node.

The first filter 260A is an acoustic wave filter arranged to filter a radio frequency signal. The first filter 260A includes one or more acoustic wave resonators coupled between a first radio frequency node RF1 and the common node COM. The first radio frequency node RF1 can be a transmit node or a receive node. The first filter 260A includes a BAW resonator in accordance with any suitable principles and advantages disclosed herein.

The second filter 260B can be any suitable filter arranged to filter a second radio frequency signal. The second filter 260B can be, for example, an acoustic wave filter, an acoustic wave filter that includes a BAW resonator in accordance with any suitable principles and advantages disclosed herein, an LC filter, a hybrid acoustic wave LC filter, or the like. The second filter 260B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 6B is a schematic diagram of a multiplexer 264 that includes an acoustic wave filter according to an embodiment. The multiplexer 264 includes a plurality of filters 260A to 260N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 260A to 260N each have a fixed electrical connection to the common node COM. This can be referred to as hard multiplexing or fixed multiplexing. Filters have fixed electrical connections to the common node in hard multiplexing applications.

The first filter 260A is an acoustic wave filter arranged to filter a radio frequency signal. The first filter 260A can include one or more acoustic wave devices coupled between a first radio frequency node RF1 and the common node COM. The first radio frequency node RF1 can be a transmit node or a receive node. The first filter 260A includes a BAW resonator in accordance with any suitable principles and advantages disclosed herein. The other filter(s) of the multiplexer 264 can include one or more acoustic wave filters, one or more acoustic wave filters that include a BAW resonator in accordance with any suitable principles and advantages disclosed herein, one or more LC filters, one or more hybrid acoustic wave LC filters, the like, or any suitable combination thereof.

FIG. 6C is a schematic diagram of a multiplexer 266 that includes an acoustic wave filter according to an embodiment. The multiplexer 266 is like the multiplexer 264 of FIG. 6B, except that the multiplexer 266 implements switched multiplexing. In switched multiplexing, a filter is coupled to a common node via a switch. In the multiplexer 266, the switches 267A to 267N can selectively electrically connect respective filters 260A to 260N to the common node COM. For example, the switch 267A can selectively electrically connect the first filter 260A the common node COM via the switch 267A. Any suitable number of the switches 267A to 267N can electrically a respective filter 260A to 260N to the common node COM in a given state. Similarly, any suitable number of the switches 267A to 267N can electrically isolate a respective filter 260A to 260N to the common node COM in a given state. The functionality of the switches 267A to 267N can support various carrier aggregations.

FIG. 6D is a schematic diagram of a multiplexer 268 that includes an acoustic wave filter according to an embodiment. The multiplexer 268 illustrates that a multiplexer can include any suitable combination of hard multiplexed and switched multiplexed filters. One or more acoustic wave devices in accordance with any suitable principles and advantages disclosed herein can be included in a filter (e.g., the filter 260A) that is hard multiplexed to the common node COM of the multiplexer 268. Alternatively or additionally, one or more acoustic wave devices in accordance with any suitable principles and advantages disclosed herein can be included in a filter (e.g., the filter 260N) that is switch multiplexed to the common node COM of the multiplexer 268.

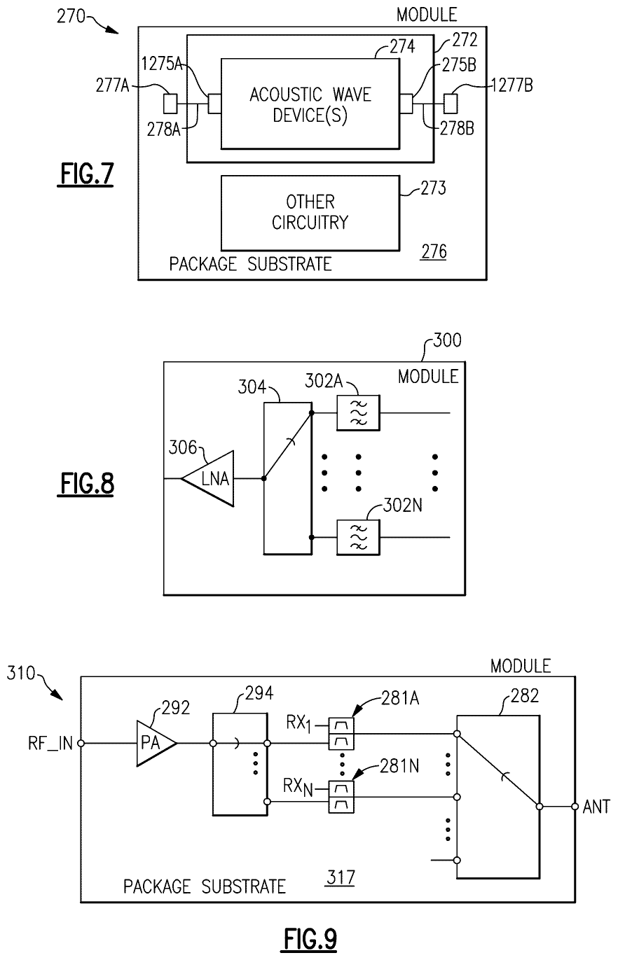

Acoustic wave devices disclosed herein can be implemented in a variety of packaged modules. Some example packaged modules will now be disclosed in which any suitable principles and advantages of the BAW devices disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 7, 8, and 9 are schematic block diagrams of illustrative packaged modules according to certain embodiments. Any suitable combination of features of these packaged modules can be implemented with each other.

FIG. 7 is a schematic diagram of a radio frequency module 270 that includes an acoustic wave component 272 according to an embodiment. The illustrated radio frequency module 270 includes the acoustic wave component 272 and other circuitry 273. The acoustic wave component 272 can include an acoustic wave filter that includes a plurality of acoustic wave devices, for example. The acoustic wave devices can be BAW devices in certain applications.

The acoustic wave component 272 shown in FIG. 7 includes one or more acoustic wave devices 274 and terminals 275A and 275B. The one or more acoustic wave devices 274 include one or more BAW devices implemented in accordance with any suitable principles and advantages disclosed herein. The terminals 275A and 274B can serve, for example, as an input contact and an output contact. Although two terminals are illustrated, any suitable number of terminals can be implemented for a particular application. The acoustic wave component 272 and the other circuitry 273 are on a common packaging substrate 276 in FIG. 7. The packaging substrate 276 can be a laminate substrate. The terminals 275A and 275B can be electrically connected to contacts 277A and 277B, respectively, on the packaging substrate 276 by way of electrical connectors 278A and 278B, respectively. The electrical connectors 278A and 278B can be bumps or wire bonds, for example.

The other circuitry 273 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 273 can include one or more radio frequency circuit elements. The other circuitry 273 can be electrically connected to the one or more acoustic wave devices 274. The radio frequency module 270 can include one or more packaging structures to, for example, provide protection and/or facilitate easier handling of the radio frequency module 270. Such a packaging structure can include an overmold structure formed over the packaging substrate 276. The overmold structure can encapsulate some or all of the components of the radio frequency module 270.

FIG. 8 is a schematic block diagram of a module 300 that includes filters 302A to 302N, a radio frequency switch 304, and a low noise amplifier 306 according to an embodiment. One or more filters of the filters 302A to 302N can include any suitable number of bulk acoustic wave devices in accordance with any suitable principles and advantages disclosed herein. Any suitable number of filters 302A to 302N can be implemented. The illustrated filters 302A to 302N are receive filters. One or more of the filters 302A to 302N can be included in a multiplexer that also includes a transmit filter and/or another receive filter. The radio frequency switch 304 can be a multi-throw radio frequency switch. The radio frequency switch 304 can electrically couple an output of a selected filter of filters 302A to 302N to the low noise amplifier 306. In some embodiments, a plurality of low noise amplifiers can be implemented. The module 300 can include diversity receive features in certain applications.

FIG. 9 is a schematic diagram of a radio frequency module 310 that includes an acoustic wave filter according to an embodiment. As illustrated, the radio frequency module 310 includes duplexers 316A to 316N, a power amplifier 312, a radio frequency switch 314 configured as a select switch, and an antenna switch 318. The radio frequency module 310 can include a package that encloses the illustrated elements. The illustrated elements can be disposed on a common packaging substrate 317. The packaging substrate 317 can be a laminate substrate, for example. A radio frequency module that includes a power amplifier can be referred to as a power amplifier module. A radio frequency module can include a subset of the elements illustrated in FIG. 9 and/or additional elements. The radio frequency module 310 may include any one of the acoustic wave filters that include at least one bulk acoustic wave resonator in accordance with any suitable principles and advantages disclosed herein.

The duplexers 316A to 316N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include a BAW device in accordance with any suitable principles and advantages disclosed herein. Similarly, one or more of the receive filters can include a BAW device in accordance with any suitable principles and advantages disclosed herein. Although FIG. 9 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 312 can amplify a radio frequency signal. The illustrated radio frequency switch 314 is a multi-throw radio frequency switch. The radio frequency switch 314 can electrically couple an output of the power amplifier 312 to a selected transmit filter of the transmit filters of the duplexers 316A to 316N. In some instances, the radio frequency switch 314 can electrically connect the output of the power amplifier 312 to more than one of the transmit filters. The antenna switch 318 can selectively couple a signal from one or more of the duplexers 316A to 316N to an antenna port ANT. The duplexers 316A to 316N can be associated with different frequency bands and/or different modes of operation (e.g., different power modes, different signaling modes, etc.).

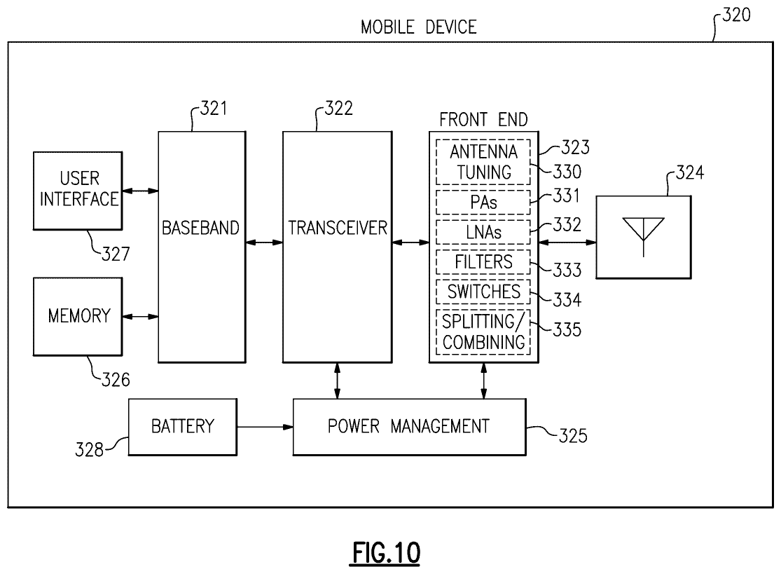

The BAW devices disclosed herein can be implemented in wireless communication devices. FIG. 10 is a schematic block diagram of a wireless communication device 320 that includes a BAW device according to an embodiment. The wireless communication device 320 can be a mobile device. The wireless communication device 320 can be any suitable wireless communication device. For instance, a wireless communication device 320 can be a mobile phone, such as a smart phone. As illustrated, the wireless communication device 320 includes a baseband system 321, a transceiver 322, a front end system 323, one or more antennas 324, a power management system 325, a memory 326, a user interface 327, and a battery 328.

The wireless communication device 320 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 322 generates RF signals for transmission and processes incoming RF signals received from the antennas 324. Various functionalities associated with the transmission and receiving of RF signals can be achieved by one or more components that are collectively represented in FIG. 10 as the transceiver 322. In one example, separate components (for instance, separate circuits or dies) can be provided for handling certain types of RF signals.

The front end system 323 aids in conditioning signals provided to and/or received from the antennas 324. In the illustrated embodiment, the front end system 323 includes antenna tuning circuitry 330, power amplifiers (PAs) 331, low noise amplifiers (LNAs) 332, filters 333, switches 334, and signal splitting/combining circuitry 335. However, other implementations are possible. The filters 333 can include one or more acoustic wave filters that include any suitable number of BAW devices in accordance with any suitable principles and advantages disclosed herein.

For example, the front end system 323 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 320 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 324 can include antennas used for a wide variety of types of communications. For example, the antennas 324 can include antennas for transmitting and/or receiving signals associated with a wide variety of frequencies and communications standards.

In certain implementations, the antennas 324 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 320 can operate with beamforming in certain implementations. For example, the front end system 323 can include amplifiers having controllable gain and phase shifters having controllable phase to provide beam formation and directivity for transmission and/or reception of signals using the antennas 324. For example, in the context of signal transmission, the amplitude and phases of the transmit signals provided to the antennas 324 are controlled such that radiated signals from the antennas 324 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 324 from a particular direction. In certain implementations, the antennas 324 include one or more arrays of antenna elements to enhance beamforming.

The baseband system 321 is coupled to the user interface 327 to facilitate processing of various user input and output (I/O), such as voice and data. The baseband system 321 provides the transceiver 322 with digital representations of transmit signals, which the transceiver 322 processes to generate RF signals for transmission. The baseband system 321 also processes digital representations of received signals provided by the transceiver 322. As shown in FIG. 10, the baseband system 321 is coupled to the memory 326 of facilitate operation of the wireless communication device 320.

The memory 326 can be used for a wide variety of purposes, such as storing data and/or instructions to facilitate the operation of the wireless communication device 220 and/or to provide storage of user information.

The power management system 325 provides a number of power management functions of the wireless communication device 320. In certain implementations, the power management system 325 includes a PA supply control circuit that controls the supply voltages of the power amplifiers 331. For example, the power management system 325 can be configured to change the supply voltage(s) provided to one or more of the power amplifiers 331 to improve efficiency, such as power added efficiency (PA E).

As shown in FIG. 10, the power management system 325 receives a battery voltage from the battery 328. The battery 328 can be any suitable battery for use in the wireless communication device 320, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 KHz to 300 GHz, such as in a frequency range from about 400 MHz to 8.5 GHZ, in FR1, in a frequency range from about 2 GHz to 10 GHz, in a frequency range from about 2 GHz to 15 GHz, or in a frequency range from 5 GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. An acoustic wave filter comprising:
a first bulk acoustic wave resonator having a first shape, a first active area, and a first shape factor; and
a second bulk acoustic wave resonator having a second shape, a second active area, and a second shape factor different than the first shape factor, the first and second bulk acoustic wave resonators being a pair of resonators electrically connected adjacent to one another, the first area and the second area being the same, and a turning distance between the first shape and the second shape being greater than zero and less than 0.3.

2. The acoustic wave filter of claim 1 wherein the first and second bulk acoustic wave resonators define a pair of series resonators.

3. The acoustic wave filter of claim 1 wherein the first and second bulk acoustic wave resonators define a pair of shunt resonators.

4. The acoustic wave filter of claim 1 wherein the difference between the first shape factor and the second shape factor is in a range between 0.001 and 0.1.

5. The acoustic wave filter of claim 1 wherein the difference between the first shape factor and the second shape factor is equal to or less than 0.05.

6. The acoustic wave filter of claim 1 wherein the difference between the first shape factor and the second shape factor is equal to or less than 0.01.

7. The acoustic wave filter of claim 1 wherein the acoustic wave filter having a first port and a second port, the first and second bulk acoustic wave resonators are a pair of series or parallel resonators closest to the first port.

8. The acoustic wave filter of claim 7 wherein the first port is an antenna port.

9. The acoustic wave filter of claim 1 wherein the first and second bulk acoustic wave resonators configured to cancel a nonlinear response.

10. The acoustic wave filter of claim 1 wherein the turning distance between the first shape and the second shape is in a range between 0.01 and 0.3.

11. A radio frequency module comprising:
the acoustic wave filter of claim 1;
radio frequency circuitry; and
a package structure enclosing the filter and the radio frequency circuitry.

12. A radio frequency system comprising:
an antenna;
an acoustic wave filter including a first bulk acoustic wave resonator having a first shape, a first active area, and a first shape factor, and a second bulk acoustic wave resonator having a second shape, a second active area, and a second shape factor different than the first shape factor, the first and second bulk acoustic wave resonators being a pair of resonators electrically connected adjacent to one another, the first area and the second area being the same, and a turning distance between the first shape and the second shape being greater than zero and less than 0.3; and
an antenna switch configured to selectively, electrically connect the antenna and a signal path that includes the filter.

13. A method of forming an acoustic wave filter, the method comprising:
providing a first bulk acoustic wave resonator on a carrier;
providing a second bulk acoustic wave resonator on the carrier, the first and second bulk acoustic wave resonators being a pair of resonators electrically connected adjacent to one another; and
varying shapes of the first and second bulk acoustic wave resonators such that the first bulk acoustic wave resonator has a first shape, a first active area, and a first shape factor and the second bulk acoustic wave resonator having a second shape, a second active area, and a second shape factor that is different than the first shape factor, and a turning distance between the first shape and the second shape being greater than zero and less than 0.3.

14. The method of claim 13 wherein the first and second bulk acoustic wave resonators define a pair of series resonators.

15. The method of claim 13 wherein the first and second bulk acoustic wave resonators define a pair of shunt resonators.

16. The method of claim 13 wherein the difference between the first shape factor and the second shape factor is equal to or less than 0.05.

17. The method of claim 13 wherein the acoustic wave filter having a first port and a second port, the first and second bulk acoustic wave resonators are a pair of series or parallel resonators closest to the first port.

18. The method of claim 17 wherein the first port is an antenna port.

19. The method of claim 13 wherein the first and second bulk acoustic wave resonators configured to cancel a nonlinear response.

20. The method of claim 13 wherein a turning distance between the first shape and the second shape is in a range between 0.01 and 0.3.
